(19) United States
(12) Patent Application Publication
(10) Pub. No.: US 2025/0038717 A1
(43) Pub. Date: Jan. 30, 2025

(54) SOFTWARE-DEFINED RADIO WITH POWER AMPLIFIER PROTECTION

(71) Applicant: BULL SAS, Les Clayes-sous-Bois (FR)

(72) Inventor: Bernard TENEZE, La Roque-d'Anthéron (FR)

(73) Assignee: BULL SAS, Les Clayes-sous-Bois (FR)

(21) Appl. No.: 18/772,811

(22) Filed: Jul. 15, 2024

(30) Foreign Application Priority Data
Jul. 24, 2023 (EP) 23306274.4

(51) Int. Cl. H03F 3/24; H04B 1/00; H04B 1/04

(52) U.S. Cl. CPC H03F 3/245; H04B 1/0003; H04B 1/0475; H03F 2200/451; H04B 2001/045

(57) ABSTRACT

The invention relates to a software-defined radio (200) comprising:
at least one processor (104) producing a digital signal,
a digital-to-analog converter, DAC (106), to convert said digital signal into an analog signal,
a physical interface (110) between the processor (104) and the DAC, and
a radio-frequency power amplifier (108) to amplify the power of said analog signal;
said software-defined radio (200) further comprising, arranged in said physical interface (110), a unit (202) for protecting said power amplifier (108) depending on:
   the average power, over a predefined reference period, of the digital signal received by said physical interface (110),
   a predefined power threshold not to be exceeded during said period.

It also relates to an electronic device comprising such a digital radio and a method of protecting a software-defined radio.

This application claims priority to European Patent Application Number 23306274.4, filed 24 Jul. 2023, the specification of which is hereby incorporated herein by reference.

### BACKGROUND OF THE INVENTION

### Field of the Invention

At least one embodiment of the invention concerns a software-defined radio equipped with power amplifier protection. It also relates to an electronic device comprising such a digital radio. It also relates to a method for protecting a software-defined radio.

The field of the invention, by way of one or more embodiments, is that of software-defined radios (SDRs), and in particular software-defined transmitting, or receiving-transmitting radios. In particular, at least one embodiment of the invention concerns the protection of the power amplifier of an SDR radio.

### Description of the Related Art

A software-defined radio, or SDR, typically comprises a CPU running a software that provides a digital data stream to be transmitted. The digital data stream, also referred to as a digital signal in the following, is converted into an analog signal in a digital-to-analog converter, DAC. The analog signal is supplied to a radio-frequency power amplifier, which amplifies said analog signal so that it can be transmitted over the air via a transmitting antenna. The software-defined radio also includes a physical interface between the CPU and the DAC: this physical interface may be an FPGA or an ASIC, for example.

A radio-frequency power amplifier can be degraded when the power of the analog signal input to it exceeds a power threshold limit for a given period of time. In some applications, such as 4G or 5G, the instantaneous power of the analog signal to be amplified may exceed the power limit, but only for very short periods of time, which poses no danger to the power amplifier. However, in the event of errors, such as bugs or malfunctions, the power limit may be exceeded for longer than the specified time, thus damaging the power amplifier.

One solution to this problem is to monitor the current drawn by the power amplifier: if the current drawn exceeds a predetermined threshold, the amplifier's power supply is cut off. This solution requires additional physical components to be added to the software-defined radio, increasing the cost and complexity of the software-defined radio. Moreover, it requires the integration of a specific function for applications requiring the power threshold to be exceeded from time to time: this increases its complexity. Finally, it is not easily adaptable to changes in the signals to be processed or the power amplifiers used.

One aim of at least one embodiment of the invention is to solve at least one of the above-mentioned shortcomings.

Another aim of at least one embodiment of the invention is to provide a software-defined radio with a simpler, less expensive power amplifier protection solution.

Another aim of at least one embodiment of the invention is to offer a software-defined radio with a power amplifier protection solution that is more flexible and adaptable to changes in the signals to be processed and/or the power amplifiers used.

### BRIEF SUMMARY OF THE INVENTION

At least one embodiment of the invention proposes to achieve at least one of the aforementioned aims with a software-defined radio comprising:
at least one processor running a software to produce a digital signal representing a data stream to be transmitted,
a digital-to-analog converter, DAC, to convert said digital signal into an analog signal,
a physical interface between said at least one processor and said DAC, and
a radio-frequency power amplifier to amplify the power of said analog signal.

According to one or more embodiments of the invention, the software-defined radio further comprises, arranged in said physical interface, a unit for protecting said power amplifier depending on:
the average power, over a predefined reference period, of the digital signal received by said physical interface,
a predefined power threshold not to be exceeded during said period.

In other words, the amplifier's protection unit is integrated into the software-defined radio's physical interface. The function of this protection unit is to prevent the RF power amplifier from receiving a signal whose average power over the reference time exceeds the power threshold, which could damage the amplifier.

Thus, at least one embodiment of the invention proposes a software-defined radio with a function of protecting the radio-frequency power amplifier, also called a power amplifier or amplifier in the following, which is directly integrated into a physical component of the software-defined radio and which does not require the addition of any further components, beyond the components forming the software-defined radio. The at least one embodiment of the invention therefore offers a simpler and less costly solution for protecting the software-defined radio's amplifier.

In addition, the software-defined radio protection solution according to at least one embodiment of the invention integrated into the physical interface comes in software form, or in the form of a modifiable configuration of a hardware component, which constitutes a more flexible and adaptable protection solution to changes in the signals to be processed and/or in the power amplifiers used. Adapting the protection solution proposed by one or more embodiments of the invention to a change in the signal to be processed, and/or in the power amplifier used, does not require any hardware change, which is easier and makes the protection solution more flexible.

In addition, the solution for protecting the software-defined radio according to at least one embodiment of the invention is based on the average power of the digital signal supplied by the processor, and not on the instantaneous power of said signal, which enables it to be used in 4G or 5G type applications, where the instantaneous power of the signal may occasionally exceed the power limit threshold.

In this document, “software-defined radio” means a software-defined radio-frequency transmitter, or a software-defined radio-frequency transceiver.

In one or more embodiments, the protective unit may comprise:
a module for calculating the average power, over the reference period, of the digital signal received by the physical interface,
a comparator comparing said calculated average power with the power threshold, and
a stage for modifying the instantaneous power of the digital signal supplied to the DAC, when said average power reaches said power threshold.

Alternatively, in one or more embodiments, the instantaneous power calculation module and/or comparator can be located in other components of the software-defined radio, for example in the processor that supplies the digital signal. This information can be supplied to the physical interface at the same time as the digital signal.

The instantaneous power modification stage can be configured to modify, and in particular decrease, the instantaneous power of the digital signal, for a period of time, called the delay time. This delay time can be predetermined. For example, and without loss of generality, the delay time can be equal to the reference period.

In one or more embodiments, the modification stage may include means for stopping the supply of the digital signal to the DAC.

In this case, when the average power over the reference time reaches or exceeds the power threshold, the digital signal received from the processor is no longer transmitted to the DAC. In other words, the software-defined radio no longer transmits a signal.

Of course, this is a degraded mode, as it causes the software-defined radio to shut down.

In one or more embodiments, the modification stage can include a reducer to reduce the power of the digital signal received at the input of the physical interface.

In this case, the physical interface continues to transmit the digital signal to the DAC, after reducing the signal's instantaneous power.

In particular, the instantaneous power of the digital signal can be reduced by applying a gain of less than 1 to said digital signal.

The value of the gain applied by the reducer depends on the instantaneous power of the digital signal and on the power threshold.

According to at least one embodiment, the value of the gain can be calculated according to the following relationship:

Gain=(power threshold)/(maximum instantaneous power)

The physical interface may be, or may comprise, any type of programmable physical component.

In one or more embodiments, the physical interface may comprise, or may be, a field-programmable gate array (FPGA) or application-specific integrated circuit (ASIC).

According to at least one embodiment of the invention, an electronic device comprising a software-defined radio according to one or more embodiments of the invention is proposed.

The electronic device can be any type of device, in particular a radio-frequency device designed to emit, or emitting, a radio-frequency signal, and in particular a radio-frequency signal representing data.

According to non-limiting examples, the device according to one or more embodiments of the invention may be:
a Wifi transmitter,
a Bluetooth® transmitter,
a terrestrial digital radio transmitter (DAB stands for “Digital Audio Broadcasting”),
a digital mobile radio (DMR) transmitter,
etc.

According to at least one embodiment of the invention, a method for protecting a software-defined radio is proposed, said software-defined radio comprising:
at least one processor running a software to produce a digital signal representing a data stream to be transmitted,
a digital-to-analog converter, DAC, to convert said digital signal into an analog signal,
a physical interface between said at least one processor and said DAC, and
a radio-frequency power amplifier to amplify the power of said analog signal supplied by the DAC;
   said method comprising an execution, within said physical interface, of a protection function of said power amplifier comprising the following steps:
calculating the average power, over a predefined reference period, of the digital signal received by said physical interface,
comparing said power with a predefined power threshold not to be exceeded during said reference time, and
when said average power reaches the power limit threshold, reducing the instantaneous power of said digital signal supplied to the DAC.

The method according to one or more embodiments of the invention provides the same advantages as those described above with reference to the software-defined radio according to at least one embodiment of the invention.

In particular, the step of reducing the instantaneous power can be carried out for a predetermined period of time, known as the delay time.

In this way, the process according to at least one embodiment of the invention makes it possible to reduce the average power of the signal supplied to the DAC, and therefore to the power amplifier.

The instantaneous power reduction step can be performed in several ways.

In particular, the step of reducing instantaneous power can be performed by applying a gain of less than 1 to the digital signal received at the input of the physical interface.

Generally, the method according to one or more embodiments of the invention can comprise, in terms of technical means, all the optional features described above with reference to the software-defined ratio and which are not mentioned herein, in detail, for brevity.

### BRIEF DESCRIPTION OF THE DRAWINGS

Other benefits and features shall become evident upon examining the detailed description of entirely non-limiting embodiments, and from the appended drawings in which:

FIG. 1 is a schematic representation of an exemplary embodiment of a software-defined radio of the prior art;

FIG. 2 is a schematic representation of a non-limiting example of a software-defined radio according to one or more embodiments of the invention;

FIG. 3 is a schematic representation of a non-limiting example of a software-defined radio according to one or more embodiments of the invention; and

FIG. 4 is a schematic representation of a non-limiting example of a method according to one or more embodiments of the invention.

### DETAILED DESCRIPTION OF THE INVENTION

It is clearly understood that the one or more embodiments that will be described hereafter are by no means limiting. In particular, it is possible to imagine variants of the one or more embodiments of the invention that comprise only a selection of the features disclosed hereinafter in isolation from the other features disclosed, if this selection of features is sufficient to confer a technical benefit or to differentiate the one or more embodiments of the invention with respect to the prior art. This selection comprises at least one preferably functional feature which is free of structural details, or only has a portion of the structural details if this portion alone is sufficient to confer a technical benefit or to differentiate the one or more embodiments of the invention with respect to the prior art.

In particular, all of the described variants and embodiments can be combined with each other if there is no technical obstacle to this combination.

In the figures and in the remainder of the description, the same reference has been used for the features that are common to several figures.

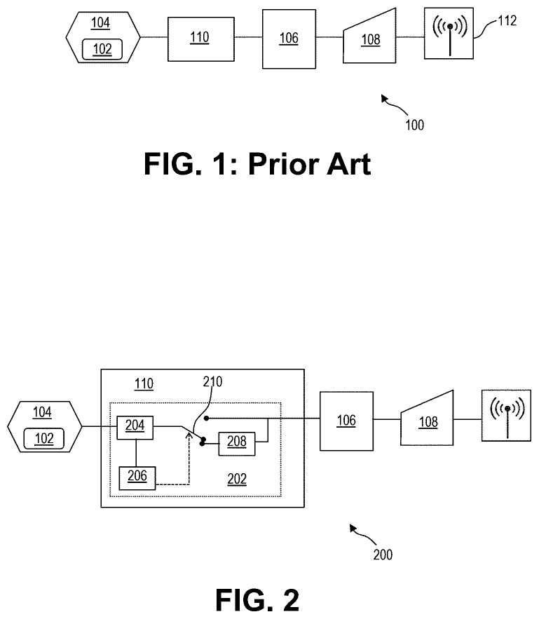

FIG. 1 is a schematic representation of a software-defined radio of the prior art.

The software-defined radio 100, shown in FIG. 1, comprises software 102, or a computer program, producing digital data, or a digital data stream, to be transmitted by the software-defined radio. The software can be of any type, and the data to be transmitted can be of any type. For example, the digital data may be communication data between a first device integrating the software-defined radio and another device comprising a radio frequency receiver. The data can be data representing music, video, data representing the result of a calculation, data representing the result of measurements of a physical quantity, and so on.

Typically, software 102 is executed in at least one computer or processor, CPU, 104. A single CPU 104 is shown in FIG. 1, without loss of generality.

The software-defined radio 100 further comprises a digital-to-analog converter, DAC, 106 for turning the digital data generated in the CPU 104, into an analog signal.

The analog signal generated by the DAC 106 is then transmitted to a radio-frequency power amplifier 108, which increases the power of the analog signal so that it can be sent into the air via a transmitting antenna. The power amplifier 108 is a component typically used in software-defined radios.

Between the CPU 104 and the DAC 106, the software-defined radio 100 comprises a physical component 110, providing the physical interface between the CPU 104 and the DAC 106. Typically, the component 110 can be a programmable electronic component. Following non-limiting examples, the component 110 can be an FPGA or an ASIC. The component 110 acts as an interface between the CPU and the DAC, transmitting the digital signal generated in the CPU to the DAC for conversion into an analog signal.

Optionally, the software-defined radio 100 may comprise a transmission antenna 112, connected directly or indirectly to the power amplifier 108, to transmit the amplified analog signal supplied by the power amplifier 108 into the air.

The software-defined radio 100 shown in FIG. 1 features the classic architecture of a software-defined radio in the prior art. In this architecture, the power amplifier 108 can receive an analog signal whose average power, over a given reference time, may exceed a power threshold that said amplifier cannot withstand. In such a case, the power amplifier 108 may be damaged, rendering the software-defined radio 100 non-functional. It is then necessary to replace the power amplifier 108, which involves the time-consuming physical disassembly and replacement of the power amplifier 108.

The one or more embodiments of the invention provide a solution to this problem.

FIG. 2 is a schematic representation of a non-limiting example of a software-defined radio according to one or more embodiments of the invention.

The software-defined radio 200 depicted in FIG. 2 comprises all of the elements of the software-defined radio 100 of FIG. 1, by way of at least one embodiment.

In addition, the software-defined radio 200 comprises a unit 202 for protecting the power amplifier 108, integrated in the component 110 providing the physical interface between the CPU 104 and the DAC 106.

This protection unit 202 is in the form of a software program, or configuration, applied to the component 110 and does not require any additional physical components, so that the software-defined radio 200 comprises no more physical components than the software-defined radio 100 of the prior art.

The function of the protection unit 202 is to:
determine the average power, over a predefined reference period, of the digital signal received from the CPU 104; and
reduce the instantaneous power of said digital signal when said average power exceeds a predefined power threshold.

The predefined power threshold corresponds to the average power limit that the power amplifier 108 can tolerate, over the reference period, without being degraded/damaged. The power threshold, for a reference period, depends on the power amplifier 108. In this way, it is possible to define this power threshold by configuring component 110, and thus adapt both to changes in the digital signal to be processed and to changes in the power amplifier used.

In the example shown, by way of at least one embodiment, the protection unit 202 comprises a module 204 for calculating the average power of the digital signal entering the component 110. For each instant t, module 204 calculates the average power, Pₘ, of the digital signal over the time window t-D, where D is the predefined reference time.

The protection unit 202 also includes a comparator 206 configured to compare the average power Pₘ, with the power threshold, noted SP, previously defined for the power amplifier 108.

The protection unit 202 further comprises a power reducer 208. This power reducer 208 applies, to the digital signal received from the CPU, a gain, denoted G, with a value less than 1 to reduce the instantaneous power of said digital signal.

The protection unit 202 further comprises a switch 210 movable between:
a first position wherein the digital signal from the CPU is not injected into the power reducer 208 and undergoes conventional processing in component 110, and
a second position wherein the digital signal from the CPU is injected into the power reducer 208 in addition to the conventional processing of said signal in said component 110.
   In FIG. 2, the switch 210 is shown in the second position.

In the example shown, by way of at least one embodiment, the switch 210 is controlled by the comparator 206. In alternatives not shown, by way of one or more embodiments, the switch 210 can be controlled by a control module (not shown) receiving the result of the comparison performed by the comparator 206.

So, when the average power of the digital signal over the reference time, calculated by the module 204, is below the power threshold, the switch 210 is in the first position: the digital signal from the CPU 104 is not injected into the power reducer 210. The instantaneous power of the digital signal is not reduced.

When the average power of the digital signal calculated by module 204 over the defined time reaches the power threshold, the switch 210 is commanded to move to the second position, as shown in FIG. 2, according to one or more embodiments. The digital signal received by the component 110 is directed to the power reducer 208, which applies a gain G with a value less than 1 to reduce the instantaneous power of said digital signal. The digital signal, whose instantaneous power has been reduced, is communicated by the component 110 to the DAC 106.

In one or more embodiments, power reduction takes place during a so-called delay time. In this case, then switch 210 is held in the second position for the duration of said delay time, then returned to the first position after the delay time has elapsed.

As mentioned above, the power threshold depends on the power amplifier and is configurable.

Furthermore, the value of the gain G applied by the power reducer 208 depends on the instantaneous power of the digital signal and on the power threshold. The value of the gain G is also programmable.

According to at least one embodiment, the value of the gain can be calculated according to the following relationship:

G=SP/maximum instantaneous power

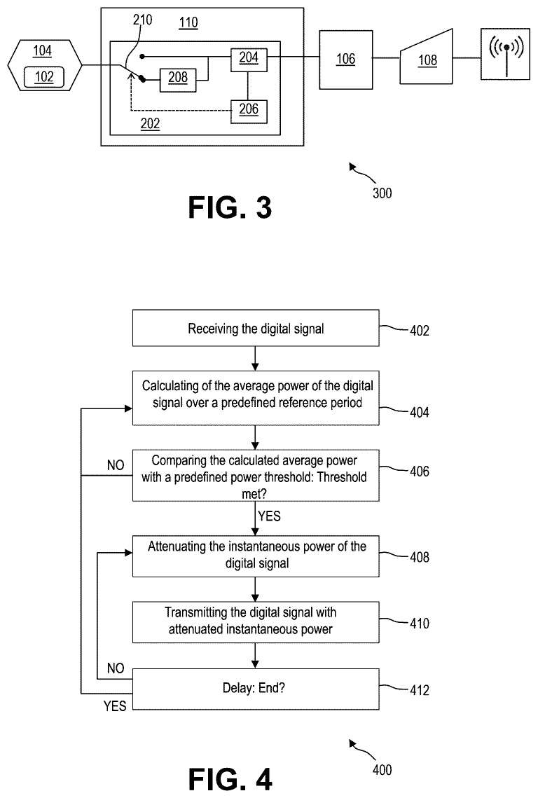

FIG. 3 is a schematic representation of another non-limiting example of a software-defined radio according to one or more embodiments of the invention.

The software-defined radio 300 depicted in FIG. 3 comprises all of the elements of the software-defined radio 200 of FIG. 2, by way of at least one embodiment.

The software-defined radio 300 differs from the software-defined radio 200 in that the module 204 for calculating the average power of the digital signal is located on the output side of component 110, i.e. downstream of the switch 210 and/or power reducer 208. In other words, the module 204 is located on the output of the protection unit 202. In this position, the module 202 can determine the power of the digital signal leaving the component 110. In this way, the module 202 can monitor the average power of the digital signal with or without power reduction, and above all, after reducing its instantaneous power, if applicable.

In this way, it is possible to better control the average power of the signal supplied to the DAC 106. In addition, it is possible to ensure that the power reduction applied by the power reducer 208 is sufficient.

FIG. 4 is a schematic depiction of another non-limiting example of a method according to one or more embodiments of the invention.

The method 400, shown in FIG. 4, can be implemented in a software-defined radio according to at least one embodiment of the invention, and in particular in any one of the software-defined radios 200 of FIG. 300, by way of at least one embodiment.

According to one or more embodiments of the invention, the method 400 is implemented in the physical interface between the software-defined radio's processor, CPU, and the software-defined radio's digital-to-analog converter, DAC.

The method 400 comprises a step 402 for receiving the digital signal, i.e. digital data, from the software-defined radio's CPU. The digital signal represents the data produced by the software running on the CPU. In particular, the digital signal can be a digital data stream.

In a step 404, the average power of the digital signal over a predetermined reference time is calculated.

In a step 406, the average power calculated in step 404 is compared with a predefined power threshold. When the average power of the digital signal is below the power threshold, no action is taken. The method resumes at step 404 with the newly received data, i.e. the new digital signal.

When the average power of the digital signal, calculated in step 404, reaches the power threshold, then in a step 408, the instantaneous power of the digital signal is attenuated, for example by applying a gain of value less than 1 in an attenuator.

In a step 410, the digital signal whose instantaneous power has been reduced is transmitted to the DAC.

Alternatively, and not shown here, by way of at least one embodiment, the method 400 can be restarted at step 404 with the new data received.

In the example shown in FIG. 4, in one or more embodiments, step 410 is carried out during a delay time which is counted down in step 412. As long as the delay time has not elapsed, the process resumes at step 408 with the new data received. When the delay time has elapsed, the method 400 resumes at step 404 with the newly received data.

The steps of the method 400 can be carried out continuously with new data generated by the software-defined radio, by way of at least one embodiment. Alternatively, in one or more embodiments, the steps of the method 400 can be performed at a predetermined frequency.

Of course, the at least one embodiment of the invention is not limited to the examples disclosed above.

1. A software-defined radio comprising:
at least one processor running a software to produce a digital signal representing a data stream to be transmitted,
a digital-to-analog converter (DAC) that converts said digital signal into an analog signal,
physical interface between said at least one processor and said DAC, and
a radio-frequency power amplifier that amplifies power of said analog signal;
wherein said software-defined radio further comprises, arranged in said physical interface, a protection unit that protects said radio-frequency power amplifier dependent on
an average power, over a predefined reference period, of the digital signal that is received by said physical interface,
a predefined power threshold not to be exceeded during said predefined reference period.

2. The software-defined radio according to claim 1, wherein the protection unit comprises
a calculator that calculates the average power, over the predefined reference period, of the digital signal received by the physical interface,
a comparator comparing said average power that is calculated with the predefined power threshold, and
a modification stage that modifies an instantaneous power of the digital signal supplied to the DAC, when said average power reaches said predefined power threshold.

3. The software-defined radio according to claim 2, wherein the modification stage is configured to stop supply of the digital signal to the DAC.

4. The software-defined radio according to claim 2, wherein the modification stage comprises a reducer or a splitter, configured to reduce power of the digital signal received at an input of the physical interface.

5. The software-defined radio according to claim 1, wherein the physical interface comprises, or is, a field-programmable gate array (FPGA) or an application-specific integrated circuit (ASIC)

6. An electronic device comprising:
a software-defined radio, said software-defined radio comprising
at least one processor running a software to produce a digital signal representing a data stream to be transmitted,
a digital-to-analog converter (DAC) that converts said digital signal into an analog signal,
a physical interface between said at least one processor and said DAC, and
a radio-frequency power amplifier that amplifies a power of said analog signal:
wherein said software-defined radio further comprises. arranged in said physical interface. a protection unit that protects said radio-frequency power amplifier dependent on
an average power, over a predefined reference period, of the digital signal that is received by said physical interface.
a predefined power threshold not to be exceeded during said predefined reference period.

7. The electronic device according to claim 6, wherein the electronic device is a Wifi transmitter, a Bluetooth® transmitter, a terrestrial digital radio transmitter, a digital mobile radio transmitter (DMR).

8. A method for protecting a software-defined radio, said software-defined radio comprising
at least one processor running a software to produce a digital signal representing a data stream to be transmitted,
a digital-to-analog converter (DAC) that converts said digital signal into an analog signal,
a physical interface between said at least one processor and said DAC, and
a radio-frequency power amplifier that amplifies a power of said analog signal supplied by the DAC;
said method comprising:
an execution, within said physical interface, of a protection function of said radio-frequency power amplifier, said execution comprising
calculating an average power, over a predefined reference period, of the digital signal received by said physical interface,
comparing said average power with a predefined power threshold not to be exceeded during said predefined reference period, and
when said average power reaches the predefined power threshold, reducing an instantaneous power of the digital signal supplied to the DAC.

9. The method according to claim 8, wherein said reducing the instantaneous power is carried out for a predetermined period of time as a delay time.

10. The method according to claim 8, wherein said reducing the instantaneous power is carried out by applying a gain of less than 1 to the digital signal that is received at an input of the physical interface.
